(19) United States
(12) Patent Application Publication
(10) Pub. No.: US 2025/0284207 A1
(43) Pub. Date: Sep. 11, 2025

(54) INSPECTION OF LITHOGRAPHIC LAYERS AND DYNAMIC DATA VIA INLINE METROLOGY

(71) Applicant: Applied Materials, Inc., Santa Clara, CA (US)

(72) Inventors: Ulrich MUELLER, Berkeley, CA (US); Thomas L. LAIDIG, Richmond, CA (US); Jang Fung CHEN, Cupertino, CA (US)

(21) Appl. No.: 19/049,659

(22) Filed: Feb. 10, 2025

Related U.S. Application Data
(60) Provisional application No. 63/562,585, filed on Mar. 7, 2024.

(51) Int. Cl. G03F 7/00; G03F 7/40; H01L 21/48

(52) U.S. Cl. CPC G03F 7/70633; G03F 7/40; G03F 7/70383; G03F 7/70608; H01L 21/485

(57) ABSTRACT

Aspects of disclosure provide a method for processing an apparatus. The method includes determining one or more altered electrical connections based on an offset between a designed component and an altered component disposed on a substrate. The method includes depositing a photoresist over the substrate and developing the photoresist to form one or more developed regions and one or more undeveloped regions. One of the one or more developed regions or the one or more undeveloped regions of the photoresist are removed to form an altered electrical connection template. The altered component and the altered electrical connection template are scanned to identify one or more misaligned regions of the altered electrical connection template. At least a portion of the altered electrical connections template is removed.

### CROSS-REFERENCE TO RELATED APPLICATIONS

This application claims benefit of U.S. provisional patent application Ser. No. 63/562,585, filed Mar. 7, 2024, which is herein incorporated by reference.

### BACKGROUND

### Field

Embodiments of the present disclosure generally relate to apparatuses, systems, and methods for processing one or more substrates. More specifically, the present disclosure relates adaptive packaging methods and apparatuses.

### Description of the Related Art

Photolithography is widely used in the manufacturing of semiconductor devices and display devices, such as liquid crystal displays (LCDs). Large area substrates are often utilized in the manufacture of LCDs. LCDs, or flat panels, are commonly used for active matrix displays, such as computers, touch panel devices, personal digital assistants (PDAs), cell phones, television monitors, and the like. Generally, flat panels include a layer of liquid crystal material forming pixels sandwiched between two plates. When power from a power supply is applied across the liquid crystal material, an amount of light passing through the liquid crystal material is controlled at pixel locations, enabling images to be generated. Other manufacturing techniques are used to produce organic light emitting diode (“OLED”) displays for use in computers, monitors and other systems providing visual output.

Microlithography techniques have been employed to create electrical features incorporated as part of the liquid crystal material layer forming the pixels. According to these techniques, a light-sensitive photoresist is applied to at least one surface of the substrate. Then, a pattern generator exposes selected areas of the light-sensitive photoresist as part of a pattern with light to cause chemical changes to the photoresist in the selective areas to prepare these selective areas for subsequent material removal and/or material addition processes to create the electrical features.

In order to continue to provide display devices and other devices at the prices demanded by consumers, new apparatuses and approaches are needed to precisely and cost-effectively create patterns on substrates, such as large area substrates.

In digital lithography tools, images from a camera are used to find a position of alignment marks so that processing may occur at a known location. In order to obtain the images, cameras are calibrated and specially chosen for pixel size, orientation (rotation), and uniformity.

One of the major challenges of microlithography systems is placement of wiring between components. Often, arrangements of components on a substrate involve a defined alignment, location, and orientation. Wiring must be placed from one component to another component on substrate. Placement of the component within on the substrate is critical. Generally, the wired connection from one component to another component is fixed (static). If one component is misaligned regarding its intended position compared to another component, then the wiring will be misaligned when created. However, misalignment can occur during processing. The problems that this causes range from components produced that are out of specification to components that do not work altogether. Problems of these sort impact the overall economic viability of the lithography process.

There is a need to enable the rapid processing, high throughput creation of wiring systems for components such that the components may be misaligned to a threshold amount during processing. Further, there is a need to enable the slight deviations in the placement of components in a defined field such that during processing, systems may adapt to the altered processing of components “in-situ” rather than a hypothetical perfect alignment that is difficult to achieve.

### SUMMARY

Aspects of disclosure provide a method for attaching wired connections between components using both design and field measured data of the components to produce accurate wired connections.

In one example embodiment, a method for processing an apparatus in a lithography system is disclosed. The method includes determining one or more altered electrical connections based on an offset between a designed component and an altered component disposed on a substrate. The method includes depositing a photoresist over the substrate and developing the photoresist to form one or more developed regions and one or more undeveloped regions. One of the one or more developed regions or the one or more undeveloped regions of the photoresist are removed to form an altered electrical connection template. The altered component and the altered electrical connection template are scanned to identify one or more misaligned regions of the altered electrical connection template. At least a portion of the altered electrical connections template is removed.

In another example embodiment, a method for processing an apparatus in a microlithography system is disclosed. The method includes determining one or more altered electrical connections based on an offset between a designed component and an altered component disposed on a substrate. A photoresist development process is performed. The photoresist development process includes depositing a photoresist over the substrate and developing the photoresist to form one or more developed regions and one or more undeveloped regions. The one or more developed regions or the one or more undeveloped regions of the photoresist are removed to form an altered electrical connection template. The altered component and the altered electrical connection template are scanned to identify one or more misaligned regions of the altered electrical connection template. At least a portion of the altered electrical connection template are removed upon identifying the one or more misaligned regions. The photoresist development process is repeated upon identifying the one or more misaligned regions. The one or more altered electrical connections are formed.

In one example embodiment, a method for processing a substrate in a microlithography system is disclosed. The method includes determining one or more altered electrical connections based on an offset between a designed component and an altered component disposed on a substrate and performing a photoresist development process. The photoresist development process includes depositing a photoresist over the substrate and developing the photoresist to form one or more developed regions and one or more undeveloped regions. The one or more developed regions or the one or more undeveloped regions of the photoresist are removed to form an altered electrical connection template. The altered component and the altered electrical connection template are scanned to identify one or more misaligned regions of the altered electrical connection template. At least a portion of the altered electrical connection template are removed upon identifying the one or more misaligned regions. The photoresist development process is repeated upon identifying one or more misaligned regions. An electrical connection material deposited in the altered electrical connection template. At least a portion of the altered electrical connections template are removed to form an altered layout plot.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a perspective view of a photolithography system, according to embodiments.

FIG. 1B is a perspective view of a photolithography system having two stages, according to embodiments.

FIG. 2A is a perspective schematic view of an image projection apparatus, according to embodiments.

FIG. 2B is a perspective schematic view of an image projection apparatus including one or more micro-LEDs, according to embodiments.

FIG. 2C is a perspective schematic view of an image projection apparatus including one or more digital micro-mirror devices (DMDs), according to embodiments.

FIG. 3 is a schematic depiction of a designed layout plot, according to embodiments.

FIG. 4 is a schematic depiction an altered layout plot, according to embodiments.

FIG. 5 is a material addition method for processing an apparatus in a lithography system, according to embodiments.

FIG. 6A-6F are schematic, top views of a substrate during the method of FIG. 5 for processing an apparatus in a lithography system, according to embodiments.

FIG. 7 is a material subtraction method for processing an apparatus in a lithography system, according to embodiments.

FIG. 8A-8G are schematic, top views of a substrate during a method of FIG. 7 for processing an apparatus in a lithography system, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to apparatuses, systems, and methods for processing one or more substrates. More specifically, the present disclosure relates to adaptive packaging methods and apparatuses.

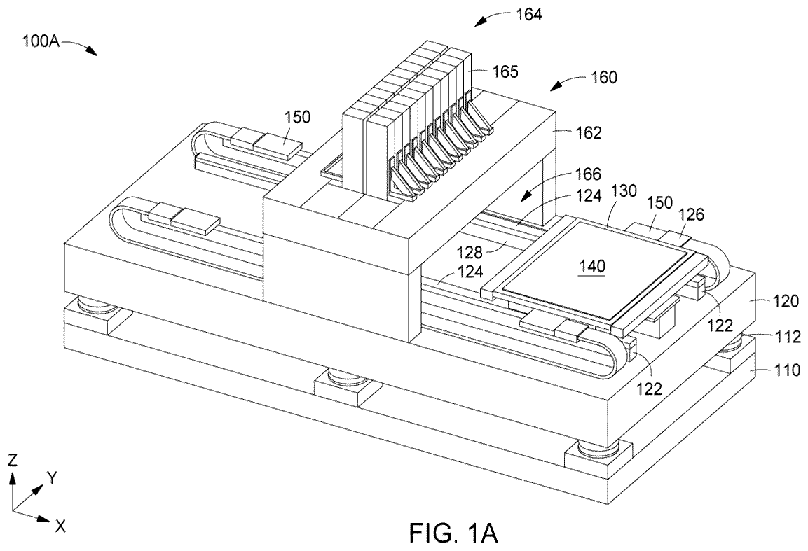

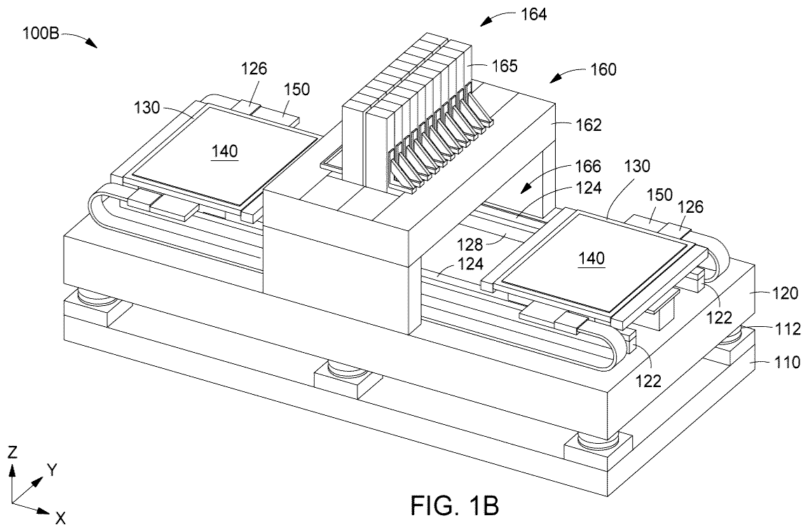

FIG. 1A is a perspective view of a photolithography system 100A according to embodiments disclosed herein. The photolithography system 100A includes a base frame 110, a slab 120, a stage 130, and a processing apparatus 160. The base frame 110 rests on the floor of a fabrication facility and supports the slab 120. Passive air isolators 112 are positioned between the base frame 110 and the slab 120. In one embodiment, the slab 120 is a monolithic piece of granite, and the stage 130 is disposed on the slab 120. A substrate 140 is supported by the stage 130. A plurality of holes are formed in the stage 130 for allowing a plurality of lift pins to extend therethrough. In some embodiments, the lift pins rise to an extended position to receive the substrate 140, such as from one or more transfer robots (not shown). The one or more transfer robots are used to load and unload a substrate 140 from the stage 130.

The substrate 140 comprises any suitable material, for example, quartz used as part of a flat panel display. In other embodiments, the substrate 140 is made of other materials. In some embodiments, the substrate 140 has a photoresist layer formed thereon. A photoresist is sensitive to radiation. A positive photoresist includes portions of the photoresist which, when exposed to radiation, will be respectively soluble to photoresist developer applied to the photoresist after the pattern is written into the photoresist. A negative photoresist includes portions of the photoresist which, when exposed to radiation, will be respectively insoluble to photoresist developer applied to the photoresist after the pattern is written into the photoresist. The chemical composition of the photoresist determines whether the photoresist will be a positive photoresist or negative photoresist. Examples of photoresists include, but are not limited to, at least one of diazonaphthoquinone, a phenol formaldehyde resin, poly(methyl methacrylate), poly(methyl glutarimide), and SU-8. In this manner, the pattern is created on a surface of the substrate 140 to form the electronic circuitry.

The photolithography system 100A includes a pair of supports 122 and a pair of tracks 124. The pair of supports 122 are disposed on the slab 120, and the slab 120 and the pair of supports 122 are a single piece of material. The pair of tracks 124 is supported by the pair of the supports 122, and the stage 130 moves along the tracks 124 in the X-direction. In one embodiment, the pair of tracks 124 is a pair of parallel magnetic channels. As shown, each track 124 of the pair of tracks 124 is linear. In other embodiments, one or more tracks 124 are non-linear. An encoder 126 is coupled to the stage 130 in order to provide location information to a controller.

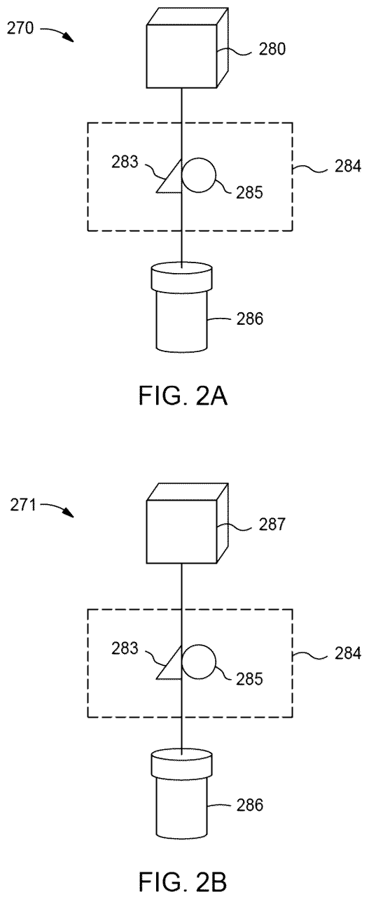

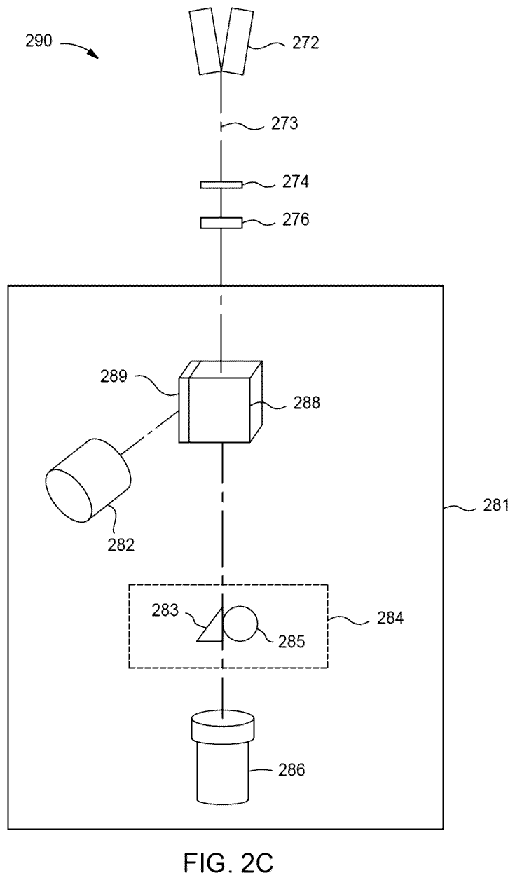

The processing apparatus 160 includes a support 162 and a processing unit 164. The support 162 is disposed on the slab 120 and includes an opening 166 for the stage 130 to pass under the processing unit 164. The processing unit 164 is supported by the support 162. In one embodiment, the processing unit 164 is a pattern generator configured to expose a photoresist in a photolithography process. In some embodiments, the pattern generator is configured to perform a maskless lithography process. The processing unit 164 includes a plurality of image projection apparatus (shown in FIGS. 2A and 2B). In one embodiment, the processing unit 164 contains as many as 84 image projection apparatuses. Each image projection apparatus is disposed in a case 165. The processing apparatus 160 is useful to perform maskless direct patterning.

During operation, the stage 130 moves in the X-direction from a loading position, as shown in FIG. 1A, to a processing position. The processing position is one or more positions of the stage 130 as the stage 130 passes under the processing unit 164. During operation, the stage 130 is lifted by a plurality of air bearings and moves along the pair of tracks 124 from the loading position to the processing position. A plurality of vertical guide air bearings are coupled to the stage 130 and positioned adjacent an inner wall 128 of each support 122 in order to stabilize the movement of the stage 130. The stage 130 also moves in the Y-direction by moving along a track 150 for processing and/or indexing the substrate 140. The stage 130 is capable of independent operation and can scan a substrate 140 in one direction and step in the other direction.

A metrology system measures the X and Y lateral position coordinates of each of the stage 130 in real time so that each of the plurality of image projection apparatus can accurately locate the patterns being written in a photoresist covered substrate. The metrology system also provides a real-time measurement of the angular position of each of the stage 130 about the vertical or Z-axis. The angular position measurement can be used to hold the angular position constant during scanning by means of a servo mechanism, or the angular position measurement can be used to apply corrections to the positions of the patterns being written on the substrate 140 by the image projection apparatus 270, shown in FIGS. 2A-2B. These techniques may be used in combination.

FIG. 1B is a perspective view of a photolithography system 100B according to embodiments disclosed herein. The system 100B is similar to the system 100; however, the system 100B includes two stages 130. Each of the two stages 130 is capable of independent operation and can scan a substrate 140 in one direction and step in the other direction. In some embodiments, when one of the two stages 130 is scanning a substrate 140, another of the two stages 130 is unloading an exposed substrate and loading the next substrate to be exposed.

While FIGS. 1A-1B depict two embodiments of a photolithography system, other systems and configurations are also contemplated herein. For example, photolithography systems including any suitable number of stages are also contemplated.

FIG. 2A is a perspective schematic view of an image projection apparatus 270 according to one embodiment, which is useful for a photolithography system, such as system 100A or system 100B. The image projection apparatus 270 includes one or more spatial light modulators 280, an alignment and inspection system 284 including a focus sensor 283 and a camera 285, and projection optics 286. The components of image projection apparatus vary depending on the spatial light modulator being used. Spatial light modulators include, but are not limited to, micro-LEDs, digital micro-mirror devices (DMDs) and liquid crystal displays (LCDs).

In operation, the spatial light modulator 280 is used to modulate one or more properties of the light, such as amplitude, phase, or polarization, which is projected through the image projection apparatus 270 and to a substrate, such as the substrate 140. The alignment and inspection system 284 is used for alignment and inspection of the components of the image projection apparatus 270. In one embodiment, the focus sensor 283 includes a plurality of lasers which are directed through the lens of the camera 285 and the back through the lens of the camera 285 and imaged onto sensors to detect whether the image projection apparatus 270 is in focus. The camera 285 is used to image the substrate 140 to ensure the alignment of the image projection apparatus 270 and photolithography system 100A or 100B is correct or within a predetermined tolerance. The projection optics 286, such as one or more lenses, is used to project the light onto the substrate, such as the substrate 140.

FIG. 2B is an image project apparatus 271 according to embodiments described herein. In the embodiment shown in FIG. 2B, the image projection apparatus 271 includes one or more micro-LEDs 287 as the spatial light modulator(s), a focus sensor and inspection system 284 and projection optics 286. In one embodiment, the image projection apparatus 271 further includes a beamsplitter. MicroLEDs are microscopic (for example, less than about 100 μm) light emitting diodes, which may be arranged in an array and used to form the individual pixels of a substrate, such as a display device. MicroLEDs include inorganic materials, such as an inorganic Gallium Nitride (GaN) material. Since micro-LEDs are self-emitting, an outside light source is not needed in the image projection apparatus 271.

In embodiments using micro-LEDs, the camera 285 is also useful to measure the image pixel pitch of the one or more micro-LEDs to calibrate for any thermal expansion happening at the micro-LED device.

FIG. 2C is an image projection apparatus 281 according to embodiments described herein. In the embodiment shown in FIG. 2C, the image projection apparatus 281 uses one or more DMDs 289 as the spatial light modulator(s). The image projection apparatus 281 is part of an image projection system 290, which includes a light source 272, an aperture 274, a lens 276, a frustrated prism assembly 288, one or more DMDs 289, and a light dump 282, in addition to the alignment and inspection system 284 and the projection optics 286. The light source 272 is any suitable light source, such as a light emitting diode (LED) or a laser, capable of producing a light having a predetermined wavelength. In one embodiment, the predetermined wavelength is in the blue or near ultraviolet (UV) range, such as less than about 450 nm. The frustrated prism assembly 288 includes a plurality of reflective surfaces. The projection optics 286 can include, as an example, a 10× objective lens. During operation of the image projection apparatus 281 shown in FIG. 2C, a light beam 273 having a predetermined wavelength, such as a wavelength in the blue range, is produced by the light source 272. The light beam 273 is reflected to the DMD 289 by the frustrated prism assembly 288. The DMD includes a plurality of mirrors, and the number of mirrors corresponds to the number of pixels to be projected. The plurality of mirrors are individually controllable, and each mirror of the plurality of mirrors is at an “on” position or “off” position, based on the mask data provided to the DMD 289 by the controller. When the light beam 273 reaches the mirrors of the DMD 289, the mirrors that are at “on” position reflect the light beam 273, i.e., forming the plurality of write beams, to the projection optics 286. The projection optics 286 then projects the write beams to the surface of the substrate 140. The mirrors that are at “off” position reflect the light beam 273 to the light dump 282 instead of the surface of the substrate 140.

In processing of materials through the lithography system, components with one or more dice are placed on a stage for processing. While a designed layout of the components may be achieved for processing, various factors may impact the designed layout. Processing speed of the lithography system may slightly move the components as the lithography system handles the components. These slight movements, for components that are small, may have drastic impact on the final product as wiring from an origination point to ending point can be small. Each component, furthermore, may have several dice, therefore many wired connections may be impacted by incorrect alignment of the component compared to the designed layout.

Aspects of the disclosure provide that, given a designed placement of one or more dice within a packaging layout as well as altered placements that may involve some errors, the designed placement may be modified or distorted to match the altered placements, thereby adaptively generating wiring for packaging of dice into a larger assembly. The disclosure further provides for measuring the location and orientation of the adaptively generated wiring to detect defects in the adaptively generated wiring prior to the deposition of the wiring material.

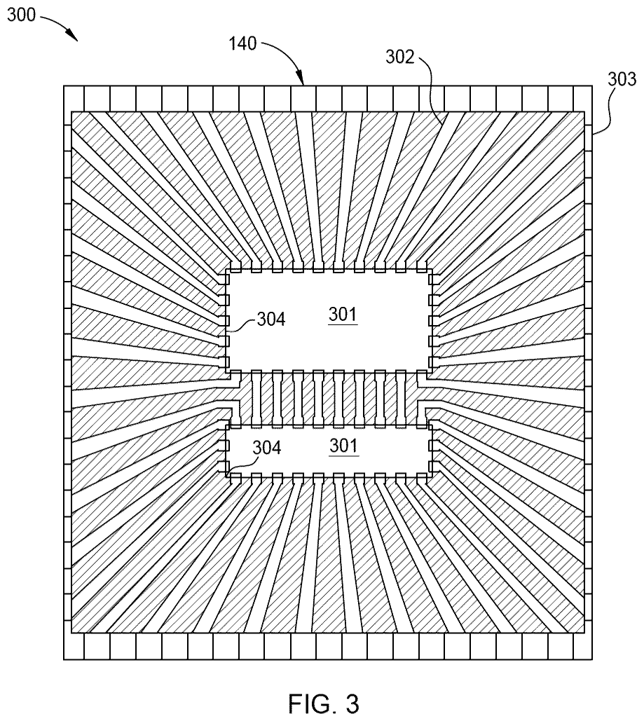

FIG. 3 is a designed layout plot 300. The designed layout plot 300 includes designed components 301 disposed on the substrate 140. The plurality of designed components 301 are connected using a plurality of designed wired connections 302 from either a fixed perimeter 303 of the substrate 140 to a designed component 301 or from designed component 301 to another designed component 301. The designed components 301 further include an edge 304. The designed wired connections 302 (e.g., designed electrical connections) may be connected to the designed components 301 at the edge 304 of the designed components 301. Such designed layout plot 300 would occur if each of the designed components 301 is placed, as intended, on a substrate 140 for processing. As will be understood, placement of components with high accuracy may be difficult. To this end, even if the designed component 301 is placed with high accuracy, shifting may occur during processing, as photolithography systems move large substrates at fast speeds.

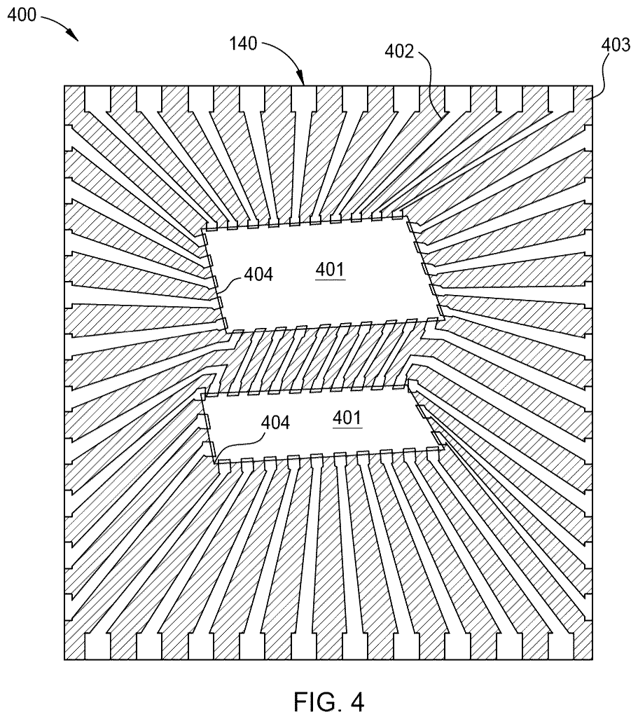

FIG. 4 is an altered layout plot 400 of an altered component 401. As can be seen, the altered component 401 is shifted from the position in FIG. 3. An altered wired connection 402 (e.g., an altered electrical connection) to the altered component 401 is therefore required in order for the altered component 401 to operate correctly. To this end an altered wired connection 402 is produced such that the altered wired connection 402 between altered components 401 or between the altered component 401 and the fixed perimeter 403 is properly established. As with the designed components 301, the altered components 401 include altered edges 404. The altered wired connections 402 may be connected to the altered components 401 at the edge 404 of the altered components 401.

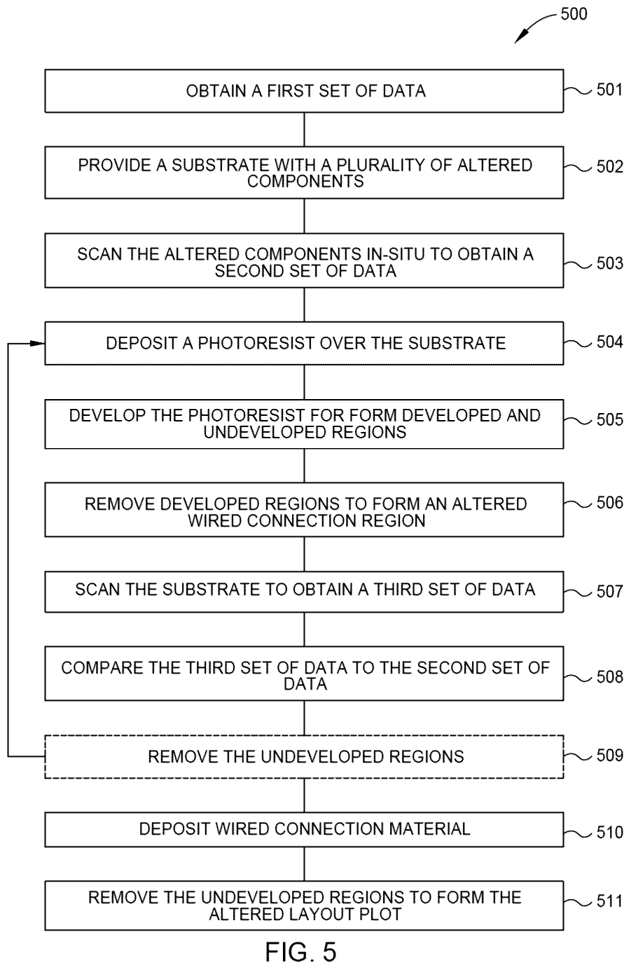

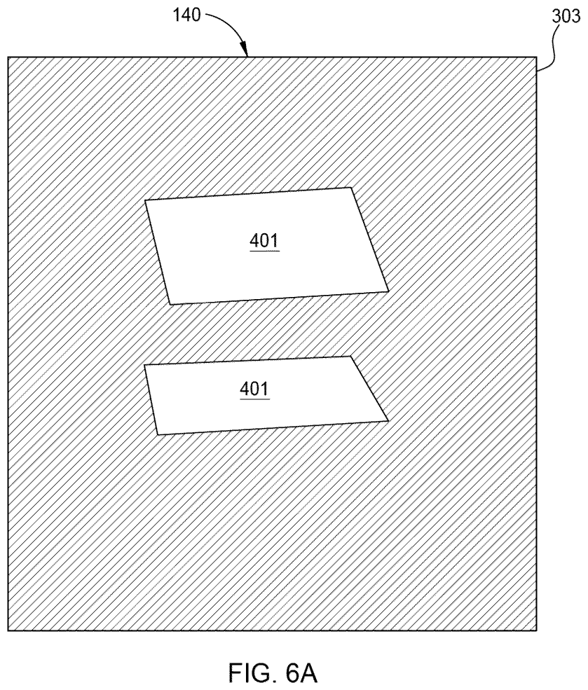

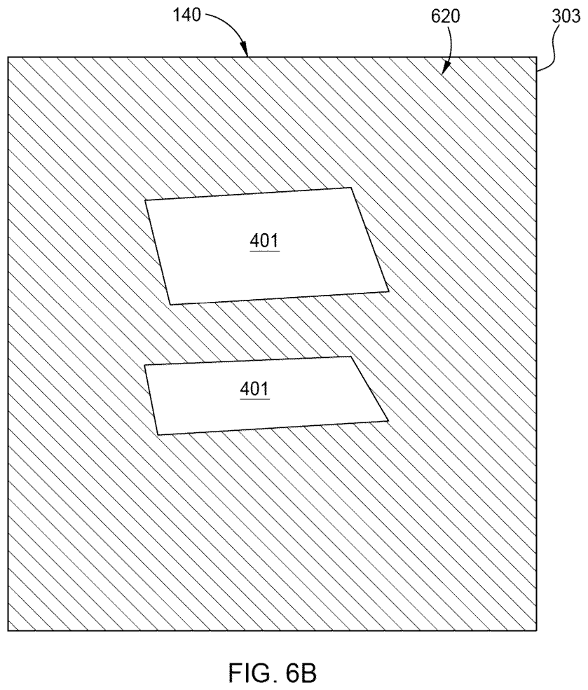

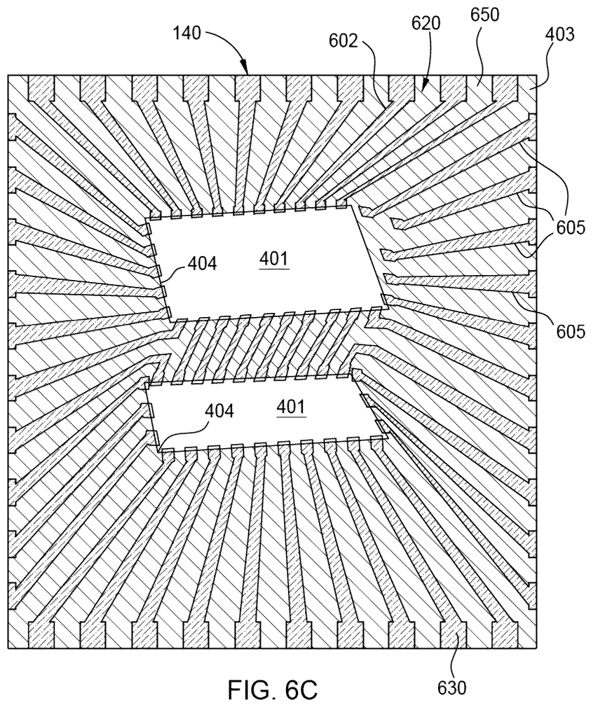

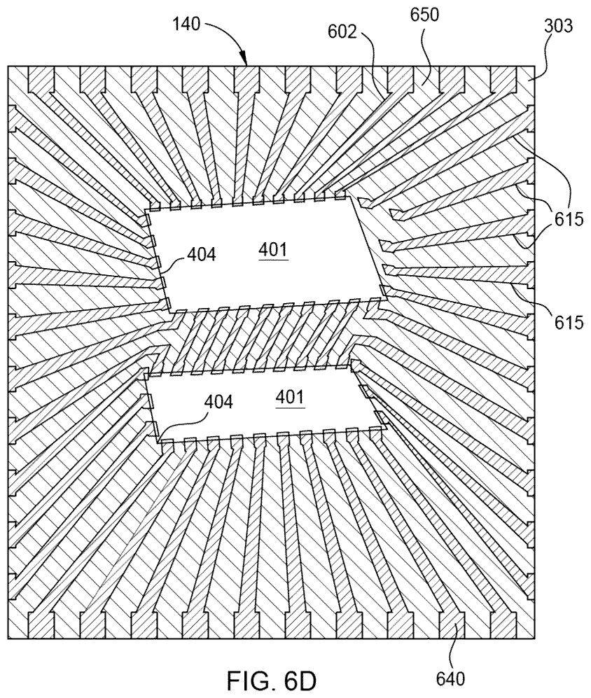

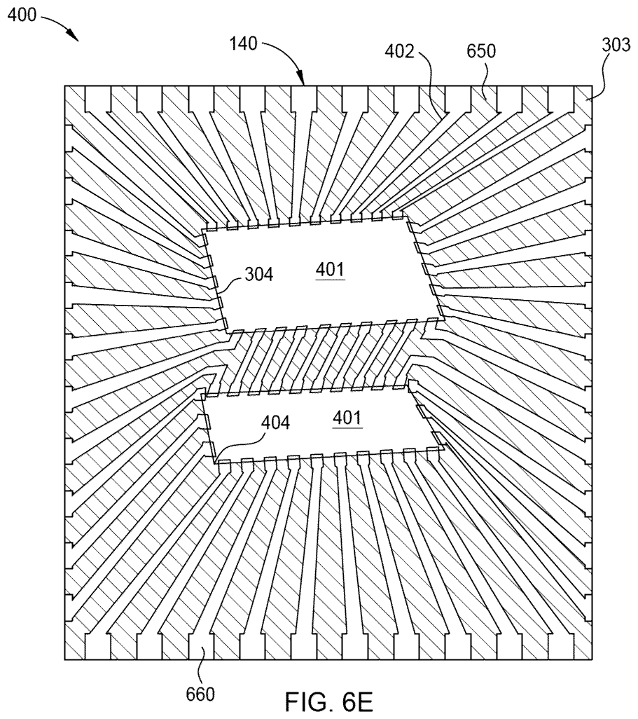

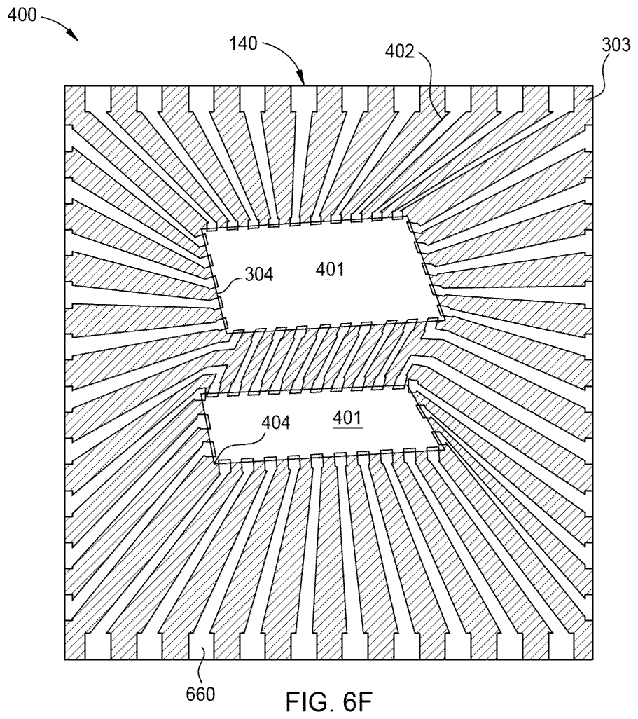

FIG. 5 is a flow chart of a method 500 for processing an apparatus in a lithography system. The method 500 is a material additional method, i.e., the altered wired connections 402 are formed by depositing a wired connection material in a wired connection region. FIGS. 6A-6F are schematic, top views of a substrate 140 during the method 500 for processing an apparatus in a lithography system. In some embodiments, the method 500 for processing the substrate 140 may be performed in a microlithography system, such as photolithography system 100A or photolithography system 100B.

At operation 501, designed data may be obtained. The designed data (e.g., a first set of data) may include coordinate data on a designed component 301 as well as a designed wired connection 302 pattern to the designed component 301 in a designed state. This designed data may be obtained from manufacturing drawings or a memory of the controller, for example. In one embodiment, position data is obtained on the designed component 301 and the designed wired connection 302 to the designed component 301 for a designed state. The designed component 301 may be any type of component that needs wiring attachment, such as, but not limited by, processors. The designed wired connection 302 may be, for example, from the designed component 301 to a fixed perimeter 303, or to a predetermined location, e.g., the edge 304 of another designed component 301.

At operation 502, as shown in FIG. 6A, a substrate 140 with a plurality of altered components 401 is provided. The substrate 140 is placed on a stage of a microlithography system. As can be understood, the altered component 401 is positioned within a defined field for processing. The altered components 401 may vary slightly from the designed component 301 due to various factors, including the ability of locating such designed components 301 accurately during initial processing of the platen (indexing table) before loading of the platen into the microlithography machine. Other factors may also cause the designed component 301 to move, such as handling of the components during microlithography steps.

At operation 503, the altered components 401 are scanned in-situ to obtain altered component data (e.g., a second set of data). To achieve an altered wired connection 402 to the altered components 401, either from the fixed perimeter 403 or in between altered components 401, the “in-situ” positioning of the altered components 401 on the substrate 140 is scanned with at least one scanning device to be able to ascertain the exact positioning of each altered component 401. In some embodiments, the stage including the altered component 401 is scanned with the at least one scanning device. The substrate 140, therefore, is moved into a position in the photolithography system 100A, 100B such that the scanning occurs for processing of coordinate data. As will be understood, scanning of the altered components 401 may also be accomplished by a separate process, and the data fed to the photolithography system 100A, 100B for use. The altered component data obtained may be stored in the memory of the controller. The altered component data may be compared to the designed data to determine any offsets that may be present in the placement of the components compared to the designed components 301. An offset may be calculated to allow the photolithography system 100A, 100B to understand the exact placement of the altered components 401. The wired connection pattern from the designed condition may then be altered using data from the offset calculation. Visual image data may also be used to determine the difference that is needed for the wired connection pattern.

Computer analysis of the data may be performed to determine the required offset. The computer analysis may not only calculate the offset, but also provide the location of the altered wired connection 402 between the altered component 401 and the fixed perimeter 403 or other altered components 401, therefore speeding processing.

In some embodiments, hardware architects may determine that slight variations from designed placement are allowable. The deviation for the wired connection and the component may be determined to be within acceptable levels. In those instances, no alteration of the wired connection may be required.

When deviations from these acceptable levels are found, a warning may be generated to the processors to allow for notification that alterations/modification of the wiring are necessary. In other embodiments, if the location and orientation of the components is outside of a maximum threshold, wired connections cannot be effectively made to the component. A separate warning may be made to the processors that the components are out of tolerance and that even with modification of the wired connection, such wired connections will be compromised.

As will be understood, designs for wired connections may take into account not only placement accuracy of the starting and ending points of the wired connection, but also wired connection length. If a length of wire would be too long for effective operation and would cause, for example, excessive latency, then a warning may be generated to the processor that such wiring, if produced, would be out of specification. In the embodiments, wired connections are understood to mean electrical connections that are established with a component, such as a die of a microprocessor.

At operation 504, as shown in FIG. 6B, a photoresist 620 is deposited over the substrate 140. The photoresist 620 is sensitive to radiation. A positive photoresist includes portions of the photoresist, which when exposed to radiation, will be respectively soluble to photoresist developer applied to the photoresist after the pattern is written into the photoresist. A negative photoresist includes portions of the photoresist, which when exposed to radiation, will be respectively insoluble to photoresist developer applied to the photoresist after the pattern is written into the photoresist. The chemical composition of the photoresist determines whether the photoresist will be a positive photoresist or negative photoresist. Examples of photoresists include, but are not limited to, at least one of diazonaphthoquinone, a phenol formaldehyde resin, poly (methyl methacrylate), poly (methyl glutarimide), and SU-8. In this manner, the pattern is created on a surface of the substrate 140 to form the electronic circuitry, e.g. wired connections.

At operation 505, as shown in FIG. 6C, the photoresist 620 is developed to form developed regions 630 and undeveloped regions 650. The photoresist 620 is developed using the photoresist developer. The photoresist developer is applied to the photoresist 620 to form a pattern corresponding to the altered wired connection 402. In some embodiments, the developed regions 630 include altered wired connection developed region 602 and misaligned altered wired connection developed region 605. In other embodiments, there are no misaligned altered wired connection developed regions 605 formed. The altered wired connection developed region 602 corresponds to the altered wired connection 402.

At operation 506, as shown in FIG. 6D, the developed regions 630 are removed to form an altered wired connection region 640 (e.g., an altered electrical connection template) and a misaligned altered wired connection region 615 (e.g., misaligned regions of the altered electrical connection template). In some embodiments, however, no misaligned altered wired connection regions 615 are formed.

At operation 507, the substrate 140 is scanned to obtain a third set of data. At operation 508, the third set of data is compared to the second set of data. In some embodiments, the third set of data is compared to the second set of data to detect the location and orientation of the altered wired connection region 640. The location and orientation of the altered wired connection region 640 may be detected using infrared metrology, or by imaging bottom vias. In some embodiments, the third set of data is compared to the second set of data in order to detect misaligned altered wired connection region 615. The misaligned altered wired connection regions 615 deviates from the altered wired connection 402. Detecting the misaligned altered wired connection region 615 enables the removal of the photoresist pattern having misaligned altered wired connection region 615 prior to the deposition of the wired connection material.

At optional operation 509 the undeveloped regions 650 of the photoresist 620 are removed. In embodiments in which misaligned altered wired connection regions 615 are detected, the undeveloped regions 650 of the photoresist 620 are removed to repeat operations 504-508. Operations 501-508 are repeated until the third set of data does not detect misaligned altered wired connection regions 615, or the misaligned altered wired connection regions 615. The removal of the photoresist 620 when misaligned altered wired connection regions 615 are detected enables an increase in defect detection before the more permanent wired connection material is deposited, thus reducing scrap and increasing throughput.

In some embodiments, hardware architects may determine that slight variations from altered wired connection 402 are allowable. The deviation of the misaligned altered wired connection regions 615 from the altered wired connection 402 may be determined to be within acceptable levels, e.g., a threshold. In those instances, no removal of the undeveloped regions 650 may be required.

In some embodiments, if the location and orientation of the misaligned altered wired connection regions 615 is outside of the threshold, wired connections cannot be effectively made to the component. A separate warning may be made to the processors that the misaligned altered wired connection regions 615 are out of tolerance and such altered wired connections 402 would be compromised.

At operation 510, as shown in FIG. 6E, a wired connection material 660 is deposited in the altered wired connection region 640 to form an altered wired connection 402. At operation 511, as shown in FIG. 6F, the undeveloped regions 650 are removed to form the altered layout plot 400.

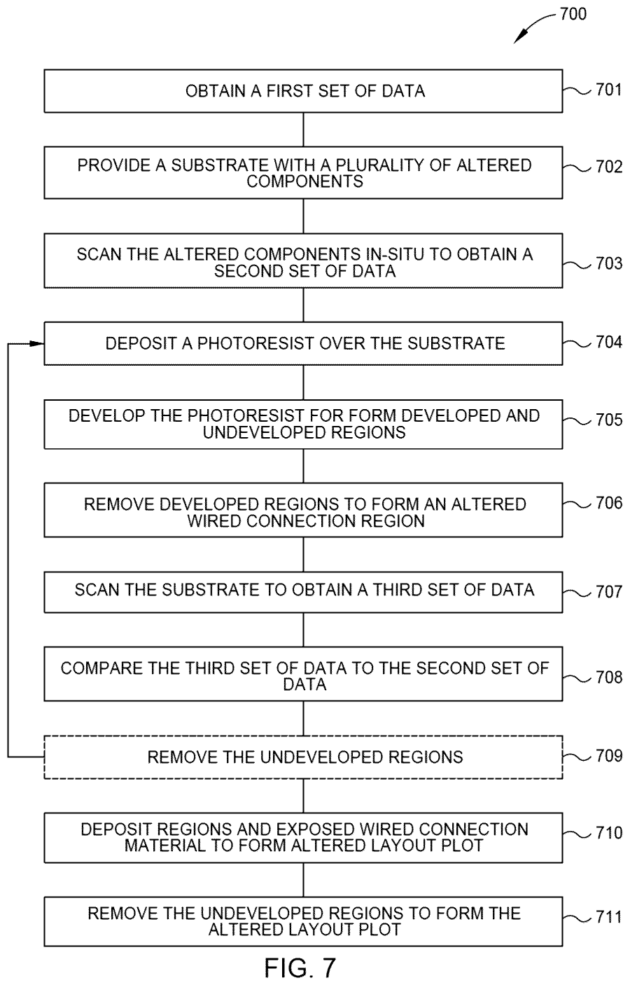

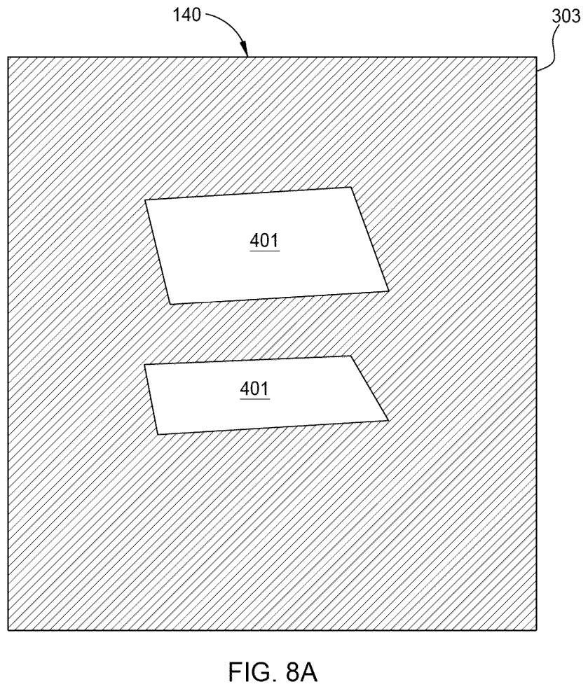

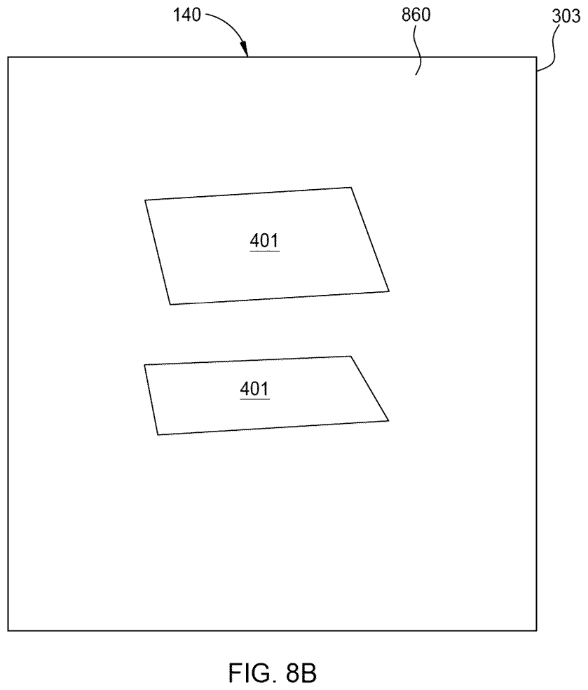

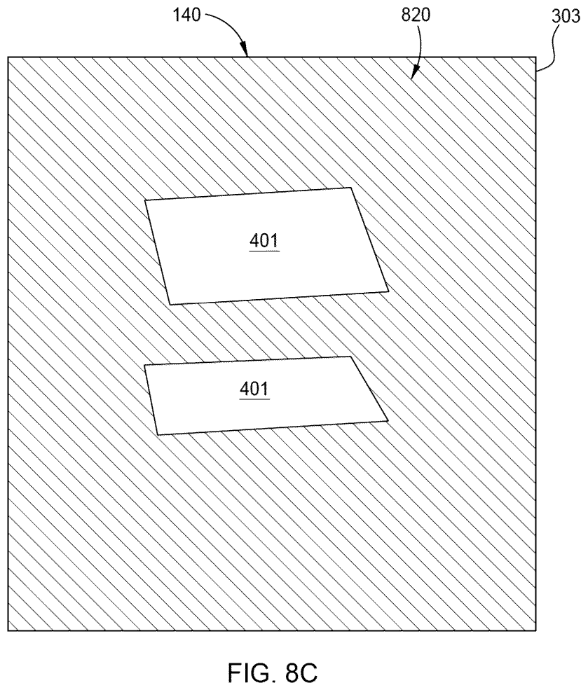

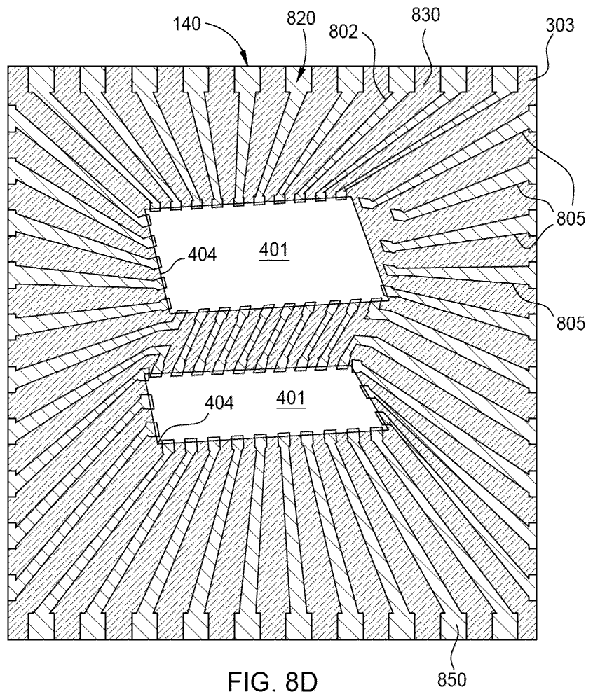

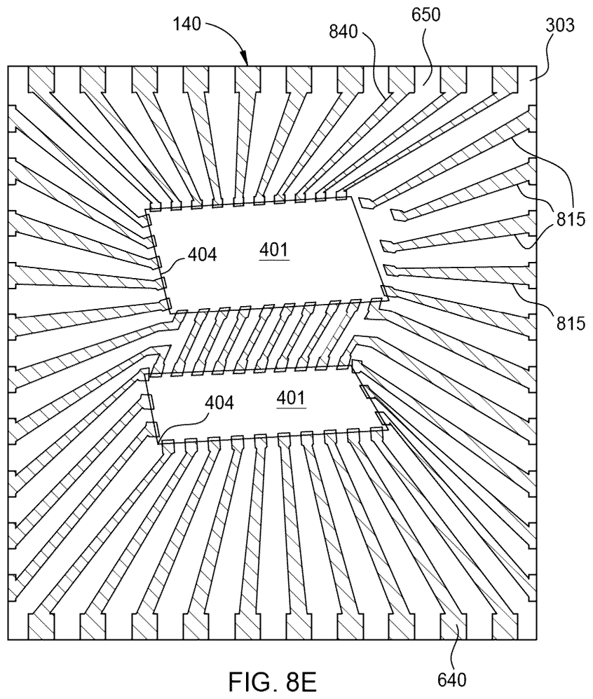

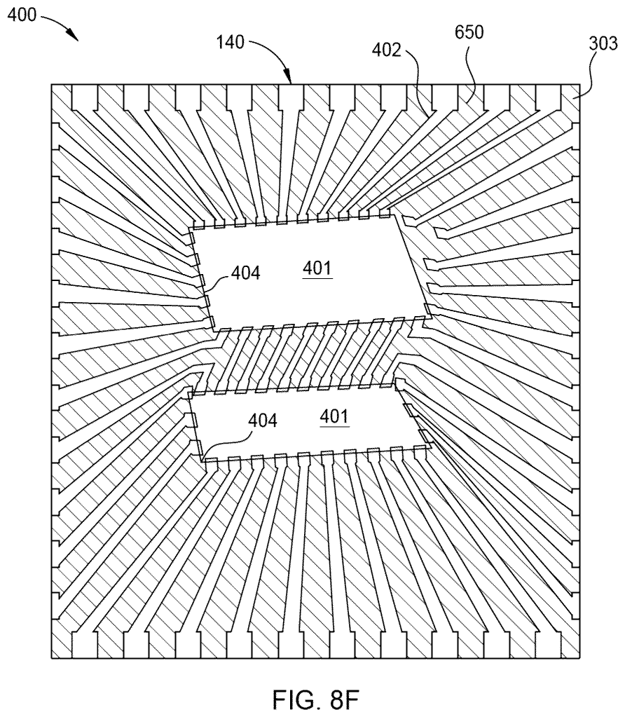

FIG. 7 is a flow chart of a method 700 for processing an apparatus in a lithography system. The method 700 is a material subtraction method, i.e., the altered wired connections 402 are formed by removing a wired connection material outside of the wired connection region. FIGS. 8A-8F are schematic, top views of a substrate 140 during the method 700 for processing an apparatus in a lithography system. In some embodiments, the method 700 for processing the substrate 140 may be performed in a microlithography system, such as photolithography system 100A or photolithography system 100B.

At operation 701 designed data may be obtained. The designed data (e.g., a first set of data) may include coordinate data on a designed component 301 as well as a designed wired connection 302 pattern to the designed component 301 in a designed state. This designed data may be obtained from manufacturing drawings or the memory of the controller, for example. In one embodiment, position data is obtained on the designed component 301 and the designed wired connection 302 to the designed component 301 for a designed state. The designed component 301 may be any type of component that needs wiring attachment, such as, but not limited by, processors. The designed wired connection 302 may be, for example, from the designed component 301 to a fixed perimeter 303, or to a predetermined location, e.g., the edge 304 of another designed component 301.

At operation 702, as shown in FIG. 8A, a substrate 140 with a plurality of altered components 401 is provided. The substrate 140 is placed on a stage of a microlithography system. As can be understood, the altered component 401 is positioned within a defined field for processing. The altered components 401 may vary slightly from the designed component 301 from various factors, including the ability of locating such designed components 301 accurately during initial processing of the platen (indexing table) before loading of the platen into the microlithography machine. Other factors may also cause the designed component 301 to move, such as handling of the components during microlithography steps.

At operation 703 the altered components 401 are scanned in-situ to obtain altered component data (e.g., a second set of data). To achieve an altered wired connection 402 to the altered components 401, either from the fixed perimeter 303 or in between altered components 401, the “in-situ” positioning of the altered components 401 on the substrate 140 are scanned with at least one scanning device to be able to ascertain the exact positioning of each altered component 401. In some embodiments, the stage is scanned including the altered component 401 with the at least one scanning device. The substrate 140, therefore, is moved into a position in the lithography system such that the scanning occurs for processing of coordinate data. As will be understood, scanning of the altered components 401 may also be accomplished by a separate process, if needed, and the data fed to the microlithography machine for use. The altered component data obtained may be stored in the controller. The second set of coordinate data may be compared to the first set of data to determine any offsets that may be present in the altered placement of the components compared to the designed positioning. An offset may be calculated to allow the microlithography machine to understand the exact placement of the components. The wired connection pattern from the designed condition may then be altered using data from the offset calculation. Visual image data may also be used to determine the difference that is needed for the wired connection pattern.

Computer analysis of the data may be performed to determine the required offset. The computer analysis may not only calculate the offset, but also provide the altered wired connection 402 locations between the altered component 401 and the fixed perimeter 303 or other altered components 401, therefore speeding processing.

In embodiments, hardware architects may determine that slight variations from designed placement are allowable. The deviation for the wired connection and the component may be determined to be within acceptable levels. In those instances, no alteration of the wired connection may be required.

When deviations from these acceptable levels are found, a warning may be generated to the processors to allow for notification that alterations/modification of the wiring are necessary. In other embodiments, if the location and orientation of the components is outside of a maximum threshold, wired connections cannot be effectively made to the component. A separate warning may be made to the processors that the components are out of tolerance and that even with modification of the wired connection, such wired connections will be compromised.

As will be understood, designs for wired connections may take into account not only placement accuracy of the starting and ending points of the wired connection, but also wired connection length. If a length of wire would be too long for effective operation and would cause, for example, excessive latency, then a warning may be generated to the processor that such wiring, if produced, would be out of specification. In the embodiments, wired connections are understood to mean electrical connections that are established with a component, such as a die of a microprocessor.

At operation 704, as shown in FIG. 8B, a wired connection material 860 is deposited over the substrate 140. The wired connection material may include aluminum, copper, tungsten, or combinations thereof.

At operation 705, as shown in FIG. 8C, a photoresist 820 is deposited over the substrate 140. The photoresist 820 is sensitive to radiation, and may be a positive photoresist or a negative photoresist. In this manner, the pattern is created on a surface of the substrate 140 to form the electronic circuitry, e.g. wired connections.

At operation 706, as shown in FIG. 8D, the photoresist 820 is developed to form developed regions 830 and undeveloped regions 850. The photoresist 820 is developed using the photoresist developer. The photoresist developer is applied to the photoresist 820 to form a pattern corresponding to the altered wired connection 402. In some embodiments, the undeveloped regions 850 include altered wired connection undeveloped regions 802 and misaligned altered wired connection undeveloped region 805. In other embodiments, there are no misaligned altered wired connection undeveloped regions 805 formed. The altered wired connection undeveloped region 802 corresponds to the altered wired connection 402.

At operation 707, as shown in FIG. 8E, the developed regions 830 are removed to form an altered wired connection region 840 (an altered electrical connection template) and a misaligned altered wired connection region 815 (e.g., misaligned regions of the altered electrical connection template). The removal of the developed regions 830 exposes the wired connection material 860. In some embodiments, however, no misaligned altered wired connection regions 815 are formed.

At operation 708, the substrate 140 is scanned to obtain a third set of data. At operation 709 the third set of data is compared to the second set of data. In some embodiments, the third set of data is compared to the second set of data in order to detect the location and orientation of the altered wired connection region 840. The location and orientation of the altered components 401 and the altered wired connection region 840 may be detected using infrared metrology, or by imaging bottom vias. In some embodiments, the third set of data is compared to the second data set in order to detect misaligned altered wired connection region 815. The misaligned altered wired connection regions 815 deviates from the altered wired connection 402. Detecting the misaligned altered wired connection region 815 enables the removal of the photoresist pattern having misaligned altered wired connection region 815 prior to the removal of the wired connection material 860 to form the altered wired connections.

In some embodiments, hardware architects may determine that slight variations from altered wired connection 402 are allowable. The deviation of the misaligned altered wired connection regions 815 from the altered wired connection 402 may be determined to be within acceptable levels, e.g., a threshold. In those instances, no removal of the undeveloped regions 650 may be required.

In other embodiments, if the location and orientation of the misaligned altered wired connection regions 815 is outside of the threshold, wired connections cannot be effectively made to the component. A separate warning may be made to the processors that the misaligned altered wired connection regions 815 are out of tolerance and such altered wired connections 402 would be compromised.

At optional operation 710, the undeveloped regions 850 of the photoresist 820 are removed. In other words, at least a portion of the altered electrical connection template is removed. In embodiments in which misaligned altered wired connection regions 815 are detected, the undeveloped regions 850 of the photoresist 820 are removed to repeat operations 705-709. Operations 705-709 are repeated until the third set of data does not detect misaligned altered wired connection regions 815. The removal of the photoresist 820 when misaligned altered wired connection regions 815 are detected enables an increase in defect detection before the more permanent wired connection material is removed, thus reducing scrap and increasing throughput.

At operation 711, as shown in FIG. 8F, the undeveloped regions 850 and the exposed wired connection material 860 are removed to form the altered layout plot 400.

In summation, the method is disclosed. The method includes determining one or more altered electrical connections based on an offset between a designed component and an altered component disposed on a substrate. The method includes depositing a photoresist over the substrate and developing the photoresist to form one or more developed regions and one or more undeveloped regions. One of the one or more developed regions or the one or more undeveloped regions of the photoresist are removed to form an altered electrical connection template. The altered component and the altered electrical connection template are scanned to identify one or more misaligned regions of the altered electrical connection template. At least a portion of the altered electrical connections template is removed. The disclosure provides for measuring the location and orientation of the adaptively generated wiring to detect defects in the adaptively generated wiring prior to the deposition of the wiring material, thereby improving throughput in fabrication.

While embodiments have been described herein, those skilled in the art, having benefit of this disclosure will appreciate that other embodiments are envisioned that do not depart from the inventive scope of the present application. Accordingly, the scope of the present claims or any subsequent related claims shall not be unduly limited by the description of the embodiments described herein.

What is claimed is:

1. A method for processing an apparatus, comprising:
determining one or more altered electrical connections based on an offset between a designed component and an altered component disposed on a substrate;
depositing a photoresist over the substrate;
developing the photoresist to form one or more developed regions and one or more undeveloped regions;
removing one of the one or more developed regions or the one or more undeveloped regions of the photoresist to form an altered electrical connection template;
scanning the altered component and the altered electrical connection template to identify one or more misaligned regions of the altered electrical connection template; and
removing at least a portion of the altered electrical connections template.

2. The method according to claim 1, further comprising, based on determining that no misaligned regions are identified, forming the one or more altered electrical connections on the altered electrical connection template.

3. The method according to claim 2, wherein the one or more developed regions correspond to the one or more altered electrical connections, and the forming of the one or more altered electrical connections comprise:
depositing an electrical connection material in the altered electrical connection template; and
removing at least a portion of the altered electrical connections template to form an altered layout plot.

4. The method according to claim 2, wherein the one or more undeveloped regions correspond to the one or more altered electrical connections, and the forming of the one or more altered electrical connections comprises:
depositing an electrical connection material over the substrate prior to depositing the photoresist; and
removing at least a portion of the altered electrical connections template and an exposed portion of the electrical connection material to form an altered layout plot, wherein removing the one or more developed regions of the photoresist to form an altered electrical connection template exposes a portion of the electrical connection material.

5. The method according to claim 1, further comprising:
based on determining that the offset is less than a threshold, setting the offset to zero.

6. The method according to claim 1, further comprising:
based on determining that the offset is greater than a threshold, generating a warning that the threshold has been exceeded.

7. The method according to claim 1, wherein the method is performed in-situ in a maskless microlithography system.

8. The method according to claim 1, further comprising providing the one or more altered electrical connections between the altered component and a second altered component.

9. The method according to claim 1, further comprising providing the one or more altered electrical connections between the altered component and a fixed perimeter of the substrate.

10. A method for processing an apparatus, comprising:
determining one or more altered electrical connections based on an offset between a designed component and an altered component disposed on a substrate;
performing a photoresist development process, comprising:
depositing a photoresist over the substrate;
developing the photoresist to form one or more developed regions and one or more undeveloped regions;
removing the one or more developed regions or the one or more undeveloped regions of the photoresist to form an altered electrical connection template;
scanning the altered component and the altered electrical connection template to identify one or more misaligned regions of the altered electrical connection template;
removing at least a portion of the altered electrical connection template upon identifying the one or more misaligned regions; and
repeating the photoresist development process upon identifying the one or more misaligned regions; and
forming the one or more altered electrical connections.

11. The method according to claim 10, wherein the one or more developed regions correspond to the one or more altered electrical connections, the forming of the one or more altered electrical connections comprises:
depositing an electrical connection material in the altered electrical connection template; and
removing at least a portion of the altered electrical connections template to form an altered layout plot.

12. The method according to claim 10, wherein the one or more undeveloped regions correspond to the one or more altered electrical connections, the forming of the one or more altered electrical connections comprises:
depositing an electrical connection material over the substrate prior to depositing the photoresist; and
removing at least a portion of the altered electrical connections template and an exposed portion of the electrical connection material to form an altered layout plot, wherein removing the one or more developed regions of the photoresist to form the altered electrical connections template exposes a portion of the electrical connection material.

13. The method according to claim 10, further comprising:
further comprising providing the one or more altered electrical connections between the altered component and a second altered component.

14. The method according to claim 10, further comprising:
comparing a first set of data of a designed component to a second set of data of the altered component; and
comparing the offset to a threshold, wherein:
when the offset is less than the threshold, setting the offset to zero; and
when the offset is greater than the threshold, generating a warning to a user that the threshold has been exceeded.

15. The method according to claim 10, wherein the one or more altered electrical connections is based upon the offset.

16. A method for processing an apparatus, comprising:
determining one or more altered electrical connections based on an offset between a designed component and an altered component disposed on a substrate;
performing a photoresist development process, comprising:
depositing a photoresist over the substrate;
developing the photoresist to form one or more developed regions and one or more undeveloped regions;
removing the one or more developed regions or the one or more undeveloped regions of the photoresist to form an altered electrical connection template;
scanning the altered component and the altered electrical connection template to identify one or more misaligned regions of the altered electrical connection template;
removing at least a portion of the altered electrical connection template upon identifying the one or more misaligned regions; and
repeating the photoresist development process upon identifying one or more misaligned regions;
depositing an electrical connection material in the altered electrical connection template; and
removing at least a portion of the altered electrical connections template to form an altered layout plot.

17. The method according to claim 16, wherein the method is performed in-situ in a maskless microlithography system.

18. The method according to claim 16, further comprising:
further comprising providing the one or more altered electrical connections between the altered component and a second altered component.

19. The method according to claim 16, further comprising:
comparing a first set of data of a designed component to a second set of data of the altered component; and
comparing the offset to a threshold, wherein:
when the offset is less than the threshold, setting the offset to zero; and
when the offset is greater than the threshold, generating a warning to a user that the threshold has been exceeded.

20. The method according to claim 16, wherein the one or more altered electrical connections is based on the offset.
